(19) United States
(12) Patent Application Publication
(10) Pub. No.: US 2003/0174043 A1
(43) Pub. Date: Sep. 18, 2003

(54) Electronically operated two-handed control unit

(76) Inventor: Hartmut Schumacher, Ebermannsdorf (DE)

Correspondence Address: HARNESS, DICKEY & PIERCE, P.L.C., P.O.BOX 8910, RESTON, VA, 20195, US

(21) Appl. No.: 10/359,611

(22) Filed: Feb. 7, 2003

(30) Foreign Application Priority Data
Feb. 7, 2002 (DE) 10205110.0

(51) Int. Cl. H04Q 1/00; H04B 1/00; H03K 17/94

(52) U.S. Cl. 340/5.1; 341/22

(57) ABSTRACT

A two-handed control unit allows machines to be operated safely. It is at the same time small, simple and cost-effective. This is achieved by the operating devices being in the form of biometric sensors. These sensors are electrically connected to evaluation electronics which evaluate identification-specific signals transmitted from the sensors, and which initiate a switching signal as a function of them.

The present application hereby claims priority under 35 U.S.C. §119 on German patent application number DE 10205110.0 filed Feb. 7, 2002, the entire contents of which are hereby incorporated herein by reference.

### FIELD OF THE INVENTION

The invention generally relates to a two-handed control unit having at least two operating devices which are used to initiate a switching operation when operated at the same time.

### BACKGROUND OF THE INVENTION

The operation of machines for industrial purposes is subject to stringent safety requirements. For safety reasons, two-handed circuits are used here, which the operator has to operate using both hands in order to initiate the function of a machine and to keep it operating during dangerous states. The requirements and the design of such two-handed control units and their circuits are described in DIN Standard EN574. The requirements stated there can be satisfied only with relatively large complicated appliances using the techniques known so far. Two-handed control panels composed of metal, that is to say whose weight is high and which have housing lengths of up to 50 cm, are typically used. The Standard says little relating to the integration of electronic elements since this field of safe electronics is still too recent and immature.

### SUMMARY OF THE INVENTION

An embodiment of the invention is thus based on an object of satisfying all the safety requirements in the Standard directly by use of suitable control components. Preferably, this is achieved with relatively small, simple and cost-effective appliances.

An object may be achieved by the operating devices being in the form of biometric sensors which are electrically connected to evaluation electronics which evaluate identification-specific signals transmitted from the sensors and initiate a switching signal as a function of them.

The solution according to an embodiment of the invention results in the following advantages.

The sensors which identify both hands of an operator satisfy all the requirements in the Standard such as “operation with two hands”, “prevention of accidental operation”, “prevention of being bypassed”, for example with one hand, with one hand and an elbow, with the lower arm, the knee, or the hip etc, “bypassing by blocking a control part” and “accidental operation”. Furthermore, it is ensured that only approved and trained operators may operate the respective machine via the two-handed circuit. In this case, it is impossible for someone who has not been trained to initiate a dangerous state of a machine. Finally, the present electronically operated two-handed control unit can be integrated directly in electronic safety circuits, for example by being connected to a safety bus.

### BRIEF DESCRIPTION OF THE DRAWINGS

An exemplary embodiment of the invention will be explained in more detail in the following text with reference to the drawings, in which:

FIGS. 1, 2, 3 show an exemplary embodiment of a two-handed control unit according to the prior art,

FIG. 4 shows a section illustration of an electronically operated two-handed control unit according to an embodiment of the present invention, and

FIGS. 5, 6, 7 show various arrangements of operating devices for the two-handed control unit in a switch panel.

### DETAILED DESCRIPTION OF TE PREFERRED EMBODIMENTS

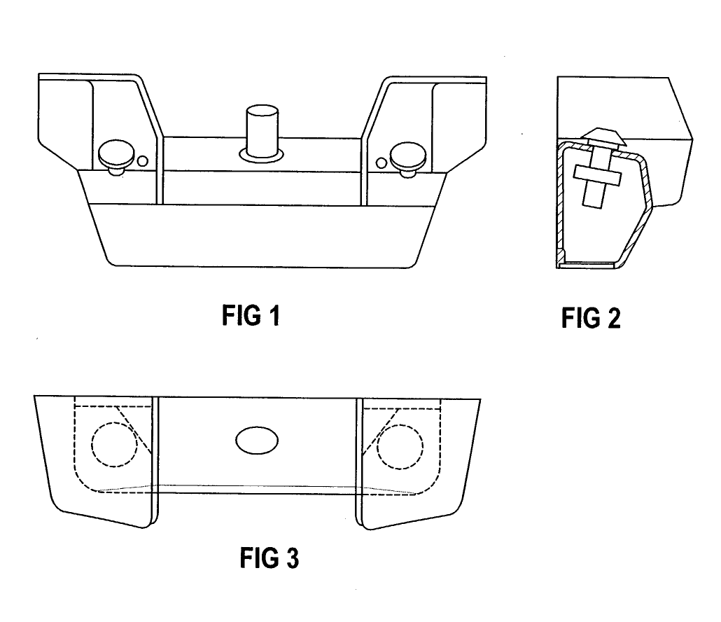

FIGS. 1, 2 and 3 show a two-handed control unit according to the prior art with two operating devices which are located relatively far apart from one another, which control unit is normally made of metal and thus also has a corresponding heavy weight. Unless any special measures are taken, this two-handed control unit can be operated by anyone, that is to say even by those who are not authorized to switch the connected machine to a dangerous state.

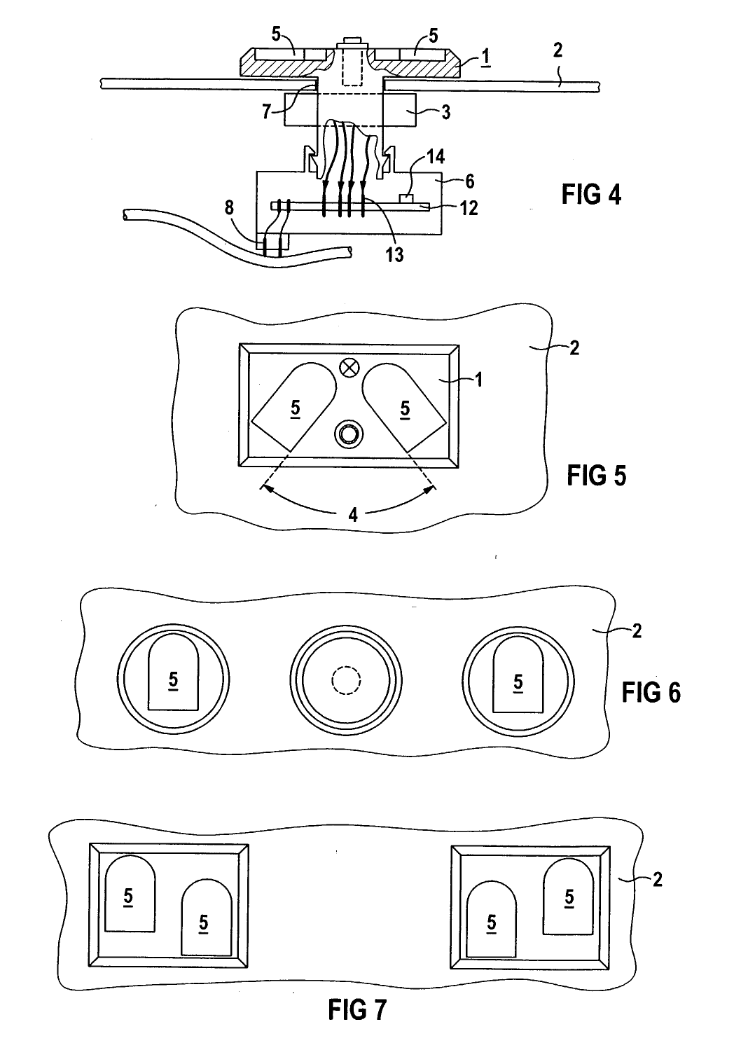

In contrast, the electronically operated two-handed control unit according to an embodiment of the invention were described in the following text with reference to FIGS. 4 to 7.

The electronically operated two-handed control unit 1 according to an embodiment of the invention is installed in a switch panel 2. On its control face, it has two biometric sensors 5, which are electrically connected to a safety signal processing unit 6 which is arranged on the rear face of the switch panel 2. The signal processing unit 6 has evaluation electronics 12 which are connected to the biometric sensors 5 via electrical conductors. This two-handed control unit 1 is secured against rotation in the opening of the switch panel 2 by use of a rotation protection device 7, and the attachment part 3 ensures that it is seated firmly in the switch panel 2. The signal processing unit 6 is provided with a connection 8, via which the evaluation electronics 12 can be connected to a safety bus 14. When the two biometric sensors 5 are operated at the same time, identification-specific signals 13 are transmitted from them to the evaluation electronics 12, which initiate a switching signal as a function of them. The sensors 5 may, for example, be finger identification sensors but, for example, sensors for the entire hand or for the balls of the hand are also suitable. The two-handed circuit 1 produces an output signal only when, for example, one sensor 5 is operated by the left finger and the other sensor 5 is operated by the right finger at the same time.

The evaluation electronics 12 have a memory 14 in which identification data is in each case stored, for example of the left hand and of the right hand of a person who is authorized for access, and, after comparison of this identification data with the identification-specific signals 13, is used to initiate a switching signal, in the event of appropriate match, only for persons who are authorized for access.

The sensors 5 are sufficiently far apart from one another that simultaneous operation by one hand is impossible. This can be precluded, for example, by skillful arrangement of the sensors 5 in that, in order to ensure a compact form, although they are arranged relatively close to one another, they are nevertheless at a suitable optimum angle with respect to one another such that it is absolutely essential to use two hands to operate them. The angle is, for example, in the form of an A, whose opening angle is at least 30°.

Alternatively, for ergonomic or design reasons, the sensors 5 may also be arranged parallel to one another, or in a V-shape, but are then placed sufficiently far apart from one another that they cannot be reached by spreading the fingers on one hand, for example at least 10 cm for a parallel arrangement or 15 cm for a V-shape.

An output signal is produced only when the sensors 5 have identified, for example, the fingers of the left hand and of the right hand with the specified simultaneity. Releasing one sensor 5 initiates the ending of the output signal. The synchronicity requirements for the signals comply with the requirements in the relevant DIN Standard.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A two-handed control unit, comprising:
at least two operating devices, adapted to initiate a switching operation when operated simultaneously, the operating devices being in the form of biometric sensors adapted to identify a left hand and a right hand and electrically connected to evaluation electronics, wherein the evaluation electronics are adapted to evaluate identification-specific signals transmitted from the sensors and initiate a switching signal as a function thereof.

2. The two-handed control unit as claimed in claim 1, wherein the sensors are in the form of finger identification sensors.

3. The two-handed control unit as claimed in claim 1, wherein the evaluation electronics include a memory in which identification data is stored for the left hand and right hand of a person who is authorized for access, and wherein the evaluation electronics is adapted to be used, after comparison of the stored identification data with the identification-specific signals, to initiate a switching signal, in the event of an appropriate match, only for persons who are authorized for access.

4. The two-hand control unit as claimed in claim 1, wherein the sensors are spaced sufficiently far apart from one another that simultaneous operation by one hand is impossible.

5. The two-handed control unit as claimed in claim 2, wherein the evaluation electronics include a memory in which identification data is stored for the left hand and right hand of a person who is authorized for access, and wherein the evaluation electronics is adapted to be used, after comparison of the stored identification data with the identification-specific signals, to initiate a switching signal, in the event of an appropriate match, only for persons who are authorized for access.

6. The two-hand control unit as claimed in claim 2, wherein the sensors are spaced sufficiently far apart from one another that simultaneous operation by one hand is impossible.

7. The two-hand control unit as claimed in claim 3, wherein the sensors are spaced sufficiently far apart from one another that simultaneous operation by one hand is impossible.

8. The two-hand control unit as claimed in claim 5, wherein the sensors are spaced sufficiently far apart from one another that simultaneous operation by one hand is impossible.

9. A two-handed control unit, comprising:
at least two operating means for initiating a switching operation when operated simultaneously, the operating means including biometric sensors adapted to identify a left hand and a right hand; and electrically connected to evaluation means for evaluating identification-specific signals transmitted from the sensors and for initiating a switching signal as a function thereof.

10. The two-handed control unit as claimed in claim 9, wherein the sensors are in the form of finger identification sensors.

11. The two-handed control unit as claimed in claim 9, wherein the evaluation means include a memory in which identification data is stored for the left hand and right hand of a person who is authorized for access, and wherein the evaluation means, after comparison of the stored identification data with the identification-specific signals, initiates the switching signal in the event of an appropriate match, only for persons who are authorized for access.

12. The two-hand control unit as claimed in claim 9, wherein the sensors are spaced sufficiently far apart from one another that simultaneous operation by one hand is impossible.

13. The two-handed control unit as claimed in claim 10, wherein the evaluation means include a memory in which identification data is stored for the left hand and right hand of a person who is authorized for access, and wherein the evaluation means, after comparison of the stored identification data with the identification-specific signals, initiates the switching signal in the event of an appropriate match, only for persons who are authorized for access.

14. The two-hand control unit as claimed in claim 10, wherein the sensors are spaced sufficiently far apart from one another that simultaneous operation by one hand is impossible.

15. The two-hand control unit as claimed in claim 11, wherein the sensors are spaced sufficiently far apart from one another that simultaneous operation by one hand is impossible.

16. The two-hand control unit as claimed in claim 13, wherein the sensors are spaced sufficiently far apart from one another that simultaneous operation by one hand is impossible.

17. The two-hand control unit as claimed in claim 1, wherein the circuit is secured against rotation by a rotation protection device.

18. The two-handed control unit as claimed in claim 9, wherein the circuit is secured against rotation by a rotation protection device.
